(19) United States
(12) Patent Application Publication
(10) Pub. No.: US 2019/0172376 A1
(43) Pub. Date: Jun. 6, 2019

(54) FOLDABLE DISPLAY PANEL AND PREPARATION METHOD THEREOF

(71) Applicant: Wuhan China Star Optoelectronics Semiconductor Display Technology Co., Ltd., Wuhan, Hubei (CN)

(72) Inventor: Juanjuan WANG, Wuhan, Hubei (CN)

(21) Appl. No.: 15/749,398

(22) PCT Filed: Jan. 2, 2018
(86) PCT No.: PCT/CN2018/070040

§ 371 Date: Jan. 31, 2018

(30) Foreign Application Priority Data
Dec. 5, 2017 (CN) 201711270910.1

(51) Int. Cl. G09F 9/30; H01L 51/56; H01L 27/32; H01L 51/00

(52) U.S. Cl. CPC G09F 9/301; H01L 51/0097; H01L 27/32; H01L 51/56

(57) ABSTRACT

The preparation method of foldable display panel is disclosed. The method includes the following steps: preparing two pressing lines on a support plate to be attached, the two pressing lines dividing the support plate into a first region, a second region, and a third region, the second region is located between the first and the third region. Through the attached contact roller sequentially attaching the first region and the second region to the OLED display screen, and the third region is naturally attached to the OLED display screen, wherein the second region is opposite to the bending area of the OLED display screen, the third region is facing the OLB area of the OLED display screen; to tear off the second region. The attached contact roller will not press into the OLB area of the OLED display screen, and will not lead the OLED display screen showing abnormal.

### RELATED APPLICATIONS

The present application is a National Phase of International Application Number PCT/CN2018/070040, filed Jan. 2, 2018, and claims the priority of China Application No. 201711270910.1, filed Dec. 5, 2017.

### FIELD OF THE DISCLOSURE

The present invention relates to the field of display technology, and in particular, to a preparation method of a foldable display panel.

### BACKGROUND

Due to the advantages of the flexible display panel being thin, not fragile, bendable, foldable and wearable, caused the flexible display panel receiving more and more attention.

When preparing a flexible display panel, the support plate to be attached needs to be attached to an OLED (Organic Light-Emitting Diode) display, and the bending area of the OLED display does not have the support plate, which attached to both sides of the bending area of the OLED display panel, wherein, there is an OLB (Bonding) area of the OLED display on one side of the bending area. Align the supporting board with the OLED display during attaching the to-be-supported board to the OLED display, then roll the supporting board on the OLED display through an attached contact roller to press the supporting board to the OLED display. However, when using the attached contact roller to roll and press the support plate, the attached contact roller will be pressed into the OLB area of the OLED display, resulting in poor bonding area, causing the OLED display to show abnormal.

### SUMMARY

In order to solve the above technical problem, the present invention provides a preparation method of a foldable display panel, when attaching the supporting plate to the OLED display panel, the attached contact roller does not press to the OLB area of the OLED display screen, will not cause the OLED to show abnormal.

The present invention provides a preparation method of a foldable display panel, comprising the following steps: preparing two pressing lines on a support plate to be attached, the two pressing lines dividing the support plate into a first region, a second region, and a third region, and the second region is located between the first region and the third region; attaching the first region and the second region onto an OLED display screen through a attached contact roller to sequentially, and attaching the third region to the OLED display screen, wherein the second region is opposite to a bending area of the OLED display screen, the third region is facing to an OLB area of the OLED display screen; tearing off the second region;

Preferably, the two pressing lines are parallel to each other.

Preferably, also includes the following steps:

bending over the OLED display screen, to paste the first region and the third region together.

Preferably, a peripheral wiring area of the OLED display screen is located at the bending area.

Preferably, the pressing lines comprise a plurality of via holes arranged at interval.

Preferably, when the support plate is attached on the OLED display screen, projection of the via hole on the OLED display screen is rectangular.

Preferably, ratio of length of the via hole on the pressing line to a connection length between the adjacent via holes is 1 or 2.

The present invention also provides a preparation method of a foldable display panel, comprising the following steps: preparing two pressing lines on a support plate to be attached, the two pressing lines dividing the support plate into a first region, a second region, and a third region, and the second region is located between the first region and the third region; attaching the first region and the second region to the OLED display screen through an attached contact roller to sequentially, and attaching the third region to the OLED display screen naturally, wherein the second region is opposite to a bending area of the OLED display screen, the third region is facing to an OLB area of the OLED display screen; tearing off the second region; wherein, the two pressing lines are parallel to each other.

Preferably, also includes the following steps:

bending over the OLED display screen, in order to paste the first region and the third region together.

Preferably, a peripheral wiring area of the OLED display screen is located at the bending area.

Preferably, the pressing line comprises a plurality of via holes arranged at interval.

Preferably, when the support plate is attached on the OLED display screen, projection of the via hole on the OLED display screen is rectangular.

Preferably, ratio of length of the via hole on the pressing line to a connection length between the adjacent via holes is 1 or 2.

The present invention also provides a preparation method of a foldable display panel, comprising the following steps:

preparing two pressing lines on a support plate to be attached, the two pressing lines dividing the support plate into a first region, a second region, and a third region, and the second region is located between the first region and the third region;
attaching the first region and the second region to the OLED display screen through an attached contact roller sequentially, and attaching the third region to the OLED display screen naturally, wherein the second region is opposite to a bending area of the OLED display screen, the third region is facing to an OLB area of the OLED display screen; tearing off the second region;

The preparation method of the foldable display panel, also comprising the following steps: bending over the OLED display screen, in order to paste the first region and the third region together.

Preferably, the two pressing lines are parallel to each other.

Preferably, a peripheral wiring area of the OLED display screen is located at the bending area.

Preferably, the pressing line comprises a plurality of via holes arranged at interval.

Preferably, when the support plate is attached on the OLED display screen, projection of the via hole on the OLED display screen is rectangular.

Preferably, ratio of length of the via hole on the pressing line to a connection length between the adjacent via holes is 1 or 2.

The implementation of the present invention has the following beneficial effects: when use the attached contact roller to roll and press the support plate, only the first region and the second region are rolled; and when the first region and the second region are attached to the OLED display screen, because the third region are located on the same support plate as the first region and the second region. Therefore, the third region can be naturally attached to the OLED display screen by the residual force of the attached roller, and does not need to roll and press through the attached contact roller, and also the OLB area of the OLED display will not roll and press onto and the third area of the support plate can be well attached to the OLED display, also will not result a bad bonding area and affect the showing of the OLED display screen.

### BRIEF DESCRIPTION OF THE DRAWINGS

To describe the technical solutions in the embodiments of the present invention or in the prior art more clearly, the following briefly introduces the accompanying drawings required for describing the embodiments or the prior art. Apparently, the accompanying drawings of the following description merely Is some embodiments of the present invention, for those skilled in the art, without any creative work under the premise can also be based on these drawings to obtain other drawings.

FIG. 1 is a flowchart of a preparation method of a foldable display panel provided by the present invention.

FIG. 2 is a schematic diagram of a support plate of preparing pressing line provided by the present invention.

FIG. 3 is a cross-sectional view of the support plate of FIG. 2 provided by the present invention, taken along the line A-A after being attached to the OLED display panel.

FIG. 4 is a schematic diagram of removing the second region in FIG. 3 provided by the present invention.

FIG. 5 is a schematic diagram of bending the flexible foldable display panel of FIG. 4 provided by the present invention.

FIG. 6 is an enlarged schematic diagram of a pressing line provided by the present invention.

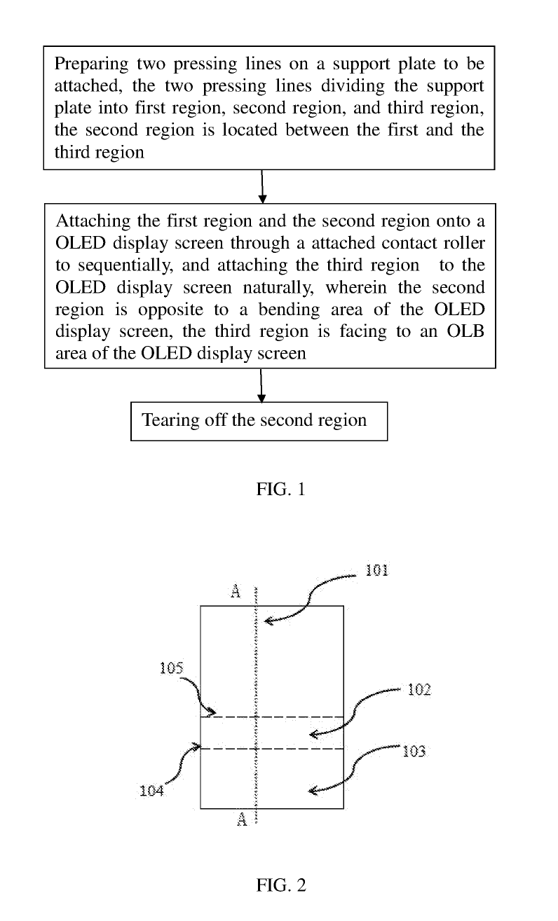

### DETAILED DESCRIPTION OF PREFERRED EMBODIMENTS

The present invention provides a preparation method of a foldable display panel, comprising the following steps:

As shown in FIG. 2, two pressing lines are prepared on a support plate 100 to be attached, and the two pressing lines divide the support plate 100 into a first region 101, a second region 102 and a third region 103, and the second region 102 is located between the first region 101 and the third region 103. Pressing lines as shown in 104 and 105 of FIG. 2.

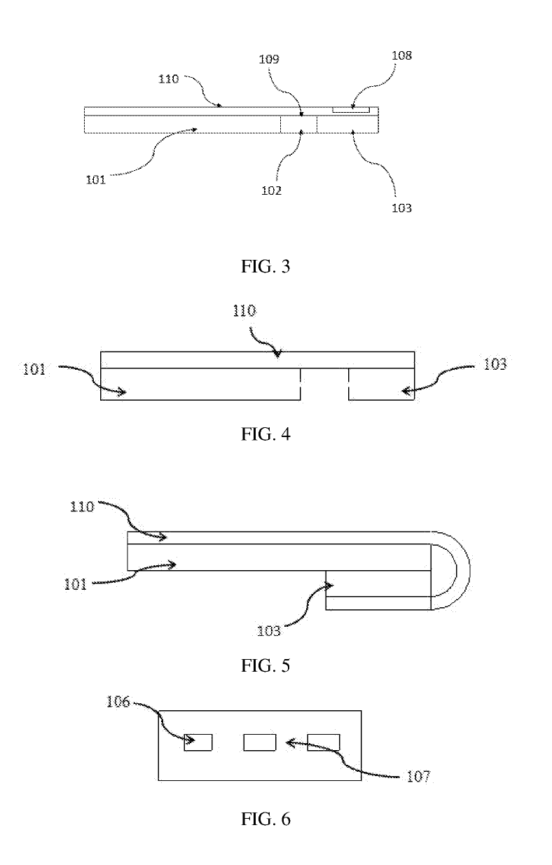

As shown in FIG. 3, the first region 101 and the second region 102 onto a OLED display screen 110 is attached through a attached contact roller sequentially, and the third region 103 is naturally attached to the OLED display screen 110, wherein the second region 102 is opposite to a bending area of the OLED display screen 110, and the third region 103 is facing to an OLB area 108 (also as bonding region) of the OLED display screen 110. The OLED display screen 110 is a flexible foldable display screen.

The second region is tear off, and the sectional view of the flexible foldable display screen after tearing, as shown in FIG. 4.

Specifically, the first region 101 and the second region 102 are sequentially attached to the OLED display screen 110 through the attached contact roller, i.e. when the support plate 100 is aligned with the OLED display screen 110 and is pasted on the front surface of the OLED, through the attached contact roller roll and press on the support plate 100, to make the first region 101 and the second region 102 of the support plate 100 paste on the OLED display screen. Herein, the support plate 100 is also a backplane or a film layer, to use for supporting and protecting the OLED display screen.

Preferably, the support plate 100 can be a PET material (Polyethylene Terephthalate).

Further, the two pressing lines are parallel to each other.

Further, the preparation method of the foldable display panel also includes the following steps:

As shown in FIG. 5, the OLED display screen 110 is bent, so that the first region 101 and the third region 103 are bonded together. Preferably, the first region 101 and the third region 103 can proceed fix by a glue.

Further, the bent area 109 is a bending area of the OLED display screen 110. The peripheral wiring area of the OLED display screen 110 is located in the bending area.

Further, as shown in FIG. 6, the pressing line includes a plurality of via holes 106 arranged at interval.

Further, when the support plate 100 is attached to the OLED display 110, and the projection of the via hole 106 on the OLED display 110 is rectangular.

Further, ratio of the length of the via hole 106 on the pressing line to connection length 107 of the adjacent via holes is 1 or 2, or some other value. The length of the via hole 106 is the length of the pressing line length direction.

To sum up, in the preparation method of a foldable display screen provided by the present invention, when the support plate 100 attaches to the OLED display screen 110, two pressing line are prepared on the support plate 100 in advance, to obtain the corresponding first region 101, the second region 102 and the third region 103. The support plate 100 is aligned with the OLED display screen 110, such that the second region 102 opposites to the bending area 109 of the OLED display screen 110. The third region 103 faces the OLED in the OLB region 108 of the display screen 110 when the attached contact roller 100 is used to roll the support plate 100. Only the first region 101 and the second region 102 are rolled. When the first region 101 and the second region 102 are attached to the OLED display screen 110, since the third region 103 and the first region 101 and the second region 102 are located on the same support plate 100, so the third region 103 can be naturally attached to the OLED display 110 (that is, by the residual force of the attached roller) and the display does not need to be rolled by the attached contact roller and thus will not roll and press the OLB area 108 of the OLED display screen 110, and the third region 103 of the support plate 100 can be well attached to the OLED display screen 110. The disclosure also will not result in bad bonding area to affect the display of the OLED display screen 110.

Before the OLED display screen 110 is bent, tearing off the second region 102 is tear off, so that the disclosure can proceed a good folding of the OLED display screen 110. The pressing line is a slit, and some of the material on the slit is linked at both ends, and some of the material is disconnected, so it is easier to tear off, and only the area between the pressing line is torn off, the first region 101 and the third region 103 on both side of the pressing line are not affected by the tearing action.

The above contents are a combine preferable specific implement manner further detailed description to this present invention, and it should not be considered that the specific implementation of the present invention is limited to these descriptions. For those ordinary skilled in the art area of the present invention, a number of simple deductions or replacements may be made without departing from the concept of the present invention, and should be considered as belonging to the scope of protection of the present invention.

What is claimed is:

1. A preparation method of a foldable display panel, comprising the following steps:
preparing two pressing lines on a support plate to be attached, the two pressing lines dividing the support plate into a first region, a second region, and a third region, and the second region is located between the first region and the third region;
attaching the first region and the second region onto a OLED display screen through an attached contact roller sequentially, and attaching the third region onto the OLED display screen naturally, wherein the second region is opposite to a bending area of the OLED display screen, the third region is facing to an OLB area of the OLED display screen; and
tearing off the second region.

2. The preparation method of the foldable display panel according to claim 1, wherein the two pressing lines are parallel to each other.

3. The preparation method of the foldable display panel according to claim 1, further comprising the following steps:
bending over the OLED display screen to paste the first region and the third region together.

4. The preparation method of the foldable display panel according to claim 1, wherein a peripheral wiring area of the OLED display screen is located at the bending area.

5. The preparation method of the foldable display panel according to claim 1, wherein the pressing lines comprises a plurality of via holes arranged at intervals.

6. The preparation method of the foldable display panel according to claim 5, wherein when the support plate is attached onto the OLED display screen, a projection of the via hole on the OLED display screen is rectangular.

7. The preparation method of the foldable display panel according to claim 5, wherein a ratio of length of the via hole on the pressing line and a connection length between adjacent via holes is 1 or 2.

8. A preparation method of a foldable display panel, comprising the following steps:
preparing two pressing lines on a support plate to be attached, the two pressing lines dividing the support plate into a first region, a second region, and a third region, and the second region is located between the first region and the third region;
attaching the first region and the second region to the OLED display screen through an attached contact roller sequentially, and attaching the third region onto the OLED display screen naturally, wherein the second region is opposite to a bending area of the OLED display screen, the third region is facing to an OLB area of the OLED display screen; and
tearing off the second region;
wherein the two pressing lines are parallel to each other.

9. The preparation method of the foldable display panel according to claim 8, further comprising the following steps:
bending over the OLED display screen, to paste the first region and the third region together.

10. The preparation method of the foldable display panel according to claim 8, wherein the peripheral wiring area of the OLED display screen is located at the bending area.

11. The preparation method of the foldable display panel according to claim 8, wherein the pressing lines comprises a plurality of via holes arranged at intervals.

12. The preparation method of the foldable display panel according to claim 11, wherein when the support plate is attached on the OLED display screen, projection of the via hole on the OLED display screen is rectangular.

13. The preparation method of the foldable display panel according to claim 11, wherein ratio of length of the via hole on the pressing line and a connection length between adjacent via holes is 1 or 2.

14. A preparation method of a foldable display panel, comprising the following steps:
preparing two pressing lines on a support plate to be attached, the two pressing lines dividing the support plate into a first region, a second region, and a third region, and the second region is located between the first region and the third region;
attaching the first region and the second region to the OLED display screen sequentially through a attached contact roller, and attaching the third region onto the OLED display screen naturally, wherein the second region is opposite to a bending area of the OLED display screen, the third region is facing to an OLB area of the OLED display screen; and
tearing off the second region;
the preparation method of the foldable display panel further comprising the following steps:
bending over the OLED display screen, paste the first region and the third region together.

15. The preparation method of the foldable display panel according to claim 14, wherein the two pressing lines are parallel to each other.

16. The preparation method of the foldable display panel according to claim 14, wherein a peripheral wiring area of the OLED display screen is located at the bending area.

17. The preparation method of the foldable display panel according to claim 14, wherein the pressing lines comprises a plurality of via holes arranged at intervals.

18. The preparation method of the foldable display panel according to claim 17, wherein when the support plate is attached to the OLED display screen, projection of the via hole on the OLED display screen is rectangular.

19. The preparation method of the foldable display panel according to claim 17, wherein ratio of the length of the via hole on the pressing line and a connection length between the adjacent via holes is 1 or 2.
